(19) United States
(12) Patent Application Publication
(10) Pub. No.: US 2026/0045936 A1
(43) Pub. Date: Feb. 12, 2026

(54) SIGNAL ISOLATOR WITH MODULATOR CIRCUIT AND METHOD OF OPERATING THE SAME

(71) Applicant: Navitas Semiconductor Limited, Dublin (IE)

(72) Inventors: Vincent DESSARD, Moint-Saint-Guibert (BE); Aimad SAIB, Gembloux (BE); Stéphane ADRIAENSEN, Limelette (BE); Xavier BAIE, Gembloux (BE); Daniel M. KINZER, El Segundo, CA (US); Marco GIANDALIA, Marina Del Rey, CA (US)

(73) Assignee: Navitas Semiconductor Limited, Dublin (IE)

(21) Appl. No.: 19/294,074

(22) Filed: Aug. 7, 2025

Related U.S. Application Data
(60) Provisional application No. 63/681,490, filed on Aug. 9, 2024.

(51) Int. Cl. H03K 3/017

(52) U.S. Cl. CPC H03K 3/017

(57) ABSTRACT

A circuit is disclosed. The circuit includes a modulator circuit referenced to a first ground and arranged to receive at least a first status identifier signal and a second status identifier signal, a pulse width modulated (PWM) signal and a first bitstream signal, and in response generate a modulated signal; an isolation capacitor coupled between to the modulator circuit and a demodulator circuit, wherein the modulator circuit is arranged to transmit the modulated signal through the isolation capacitor to the demodulator circuit; and a clock generator circuit arranged to generate a clock signal (CK0), where the PWM signal and the first bitstream signal are synchronized with CK0; and where the demodulator circuit is referenced to a second ground and is arranged to receive the modulated signal and generate output signals corresponding to the first and second status identifier signals, the PWM signal and the first bitstream signal.

### CROSS REFERENCE TO RELATED APPLICATIONS

This application claims priority to US provisional Ser. No. 63/681,490 , for “SIGNAL ISOLATOR WITH DIGITAL MULTIPLEXOR AND METHOD OF OPERATING THE SAME” filed on Aug. 9, 2024, which is hereby incorporated by reference in entirety for all purposes.

### FIELD

The described embodiments relate generally to galvanic isolation in power converters, and more particularly, the present embodiments relate to signal isolator with a modulator circuit and method of operating the same.

### BACKGROUND

Electronic devices such as computers, servers and televisions, among others, employ one or more electrical power conversion circuits to convert one form of electrical energy to another. Some electrical power conversion circuits convert a high (or low) DC voltage to a lower (or higher) DC voltage using a circuit topology called DC-DC converter. As many electronic devices are sensitive to size and efficiency of the power conversion circuit, new power converters can provide relatively higher efficiency and lower size for the new electronic devices. Power converters may utilize isolators. Isolators can be implemented to separate circuits or circuit sections of the electrical circuit to one another from undesired influence of, for example but not limited to, other circuits or circuit sections, to minimize the influence of common mode transients (CMT), influence of radiation or electromagnetic interferences, cross talk, between circuits or circuit sections. Capacitive isolation can be used in galvanic isolation, to isolate high voltages from one another or to isolate low voltage command circuits to high voltage power circuits.

### SUMMARY

In some embodiments, a circuit is disclosed. The circuit includes a modulator circuit referenced to a first ground and arranged to receive at least a first status identifier signal and a second status identifier signal, a pulse width modulated (PWM) signal and a first bitstream signal, and in response generate a modulated signal; an isolation capacitor coupled between to the modulator circuit and a demodulator circuit, wherein the modulator circuit is arranged to transmit the modulated signal through the isolation capacitor to the demodulator circuit; and a clock generator circuit arranged to generate a clock signal (CK0), wherein the PWM signal and the first bitstream signal are synchronized with CK0; and wherein the demodulator circuit is referenced to a second ground and is arranged to receive the modulated signal and generate output signals corresponding to the first and second status identifier signals, the PWM signal and the first bitstream signal.

In some embodiments, the demodulator circuit is arranged to detect CK0 when after a rising edge of PWM, a reset-set sequence is detected within a first time period T1.

In some embodiments, the demodulator circuit is further arranged to set the first bitstream signal to 1 when a set is detected within a second time period after CK0 is detected.

In some embodiments, the circuit further includes a second clock generator circuit arranged to generate a second clock signal.

In some embodiments, the demodulator circuit is further arranged to indicate that the second clock signal is active, and to indicate that the second status identifier signal is active when more than two consecutive set or two consecutive reset signals are detected.

In some embodiments, the modulator circuit is further arranged to receive a second bitstream signal.

In some embodiments, the second clock signal is mixed with the second status identifier signal and with a third status identifier signal.

In some embodiments, when the first status identifier signal is 1, the modulator circuit is disabled.

In some embodiments, the first status identifier signal corresponds to an isolated undervoltage lock-out (UVLO) signal, and the second identifier signal corresponds to an isolated overcurrent condition signal.

In some embodiments, a circuit is disclosed. The circuit includes a plurality of isolated detectors arranged to detect system operating statuses and generate a plurality of digital signals; a pulse width generation circuit arranged to generate a pulse width modulated (PWM) signal, and at least a bitstream generator circuit arranged to generate at least a time sensitive bitstream signal; and a modulator circuit arranged to receive the PWM signal and the time sensitive bitstream signal and in response, using sequence of set and reset commands, generate a single modulated signal, the modulator circuit further arranged to asynchronously modulate the plurality of digital signals onto the single modulated signal to generate an output modulated signal, and transmit the modulated output signal across an isolation capacitor to a demodulator circuit.

In some embodiments, the demodulator circuit is arranged to receive the modulated output signal and extract a reference clock from the modulated output signal.

In some embodiments, the demodulator circuit is arranged to regenerate the PWM signal, the time sensitive bitstream signal and the plurality of digital signals.

In some embodiments, the modulator circuit operates referenced to a first ground.

In some embodiments, the demodulator circuit operates referenced to a second ground.

In some embodiments, a method of operating a circuit is disclosed. The method includes providing a modulator circuit referenced to a first ground; receiving, by the modulator circuit, at least a first status identifier signal and a second status identifier signal, a pulse width modulated (PWM) signal and a first bitstream signal; generating, by the modulator circuit, a modulated signal; providing an isolation capacitor coupled between to the modulator circuit and a demodulator circuit; and transmitting, by the modulator circuit, the modulated signal through the isolation capacitor to the demodulator circuit.

In some embodiments, the method further includes generating, by a clock generator circuit, a clock signal (CK0).

In some embodiments, the method further includes synchronizing the PWM signal and the first bitstream signal with CK0.

In some embodiments, the method further includes receiving, by the demodulator circuit, the modulated signal.

In some embodiments, the method further includes generating, by the demodulator circuit, output signals corresponding to the first and second status identifier signals, the PWM signal and the first bitstream signal.

### BRIEF DESCRIPTION OF THE DRAWINGS

FIG. 1 illustrates an isolated gate driver circuit with a modulator, according to some embodiments;

FIG. 2 illustrates a modulation scheme used by the modulator circuit of FIG. 1 and the associated circuitry, according to some embodiments;

FIG. 3 illustrates an isolated gate driver circuit with a modulator having multiple bitstreams, according to some embodiments;

FIG. 4 illustrates modulation schemes used by the modulator circuit of FIG. 3, according to some embodiments;

FIG. 5 illustrates a modulation scheme used by the modulator circuit of FIG. 1 and the associated circuitry where modulated signals can send analog information instead of a bitstream, according to some embodiments;

FIG. 6 illustrates a modulation and demodulation scheme used in isolated gate drivers, according to some embodiments;

FIG. 7 illustrates a modulation scheme, according to certain embodiments;

FIG. 8 illustrates an isolated gate driver circuit with a modulator having multiple sigma/delta inputs, according to some embodiments; and

FIG. 9 illustrates a digital modulation scheme based on the scheme shown in FIG. 8, according to some embodiments.

### DETAILED DESCRIPTION

Circuits, structures, and related techniques disclosed herein relate generally to galvanic isolation in power converters. More specifically, circuits, devices and related techniques disclosed herein relate to galvanically isolated gate driver circuits used in power converters, where the gate driver circuit can include a modulator circuit arranged to transmit isolated side time-sensitive information to the non-isolated side using efficient modulation schemes. In some embodiments, the isolated side can be a isolated high-voltage side and the non-isolated side can be a non-isolated low-voltage side. In various embodiments, a modulator circuit and the associated modulation techniques enable signals to be multiplexed and transmitted to the low-voltage side using an isolator having a single isolation channel without any signal distortion. In this way, die area and system power can be saved.

In some embodiments, an isolator with a multiplexing circuit can be used to safely transmit control and/or bit-stream signals from the high-voltage side to the low-voltage side of the system. Circuits and techniques disclosed herein enable efficient transmission of various isolated system information such as status, temperature, node voltages, and many current values from the isolated high-voltage side to the non-isolated low-voltage side. In various embodiments, multiplexing of several time sensitive signals on a single isolation channel is enabled, thereby minimizing signal distortion and without an increase in the die size. Further, techniques disclosed herein can be used in power converters where the time dependent signals may be generated from the same reference clock.

Circuits and methods disclosed herein can be utilized for modulating a pulse width modulated (PWM) signal together with one or more bitstreams (such as sigma delta or other similar signals), when the same reference clock is used for those signals. Additionally, techniques disclosed herein can enable modulation of relatively slow non-time-dependent signals, such as status bits, for example, but not limited to, a fault flag and/or UVLO ready signal on top of time dependent fast signals. This is so because for the relatively slow non-time-dependent signals the propagation delay variation may not be critical. Various inventive embodiments are described herein, including methods, processes, systems, devices, and the like.

Several illustrative embodiments will now be described with respect to the accompanying drawings, which form a part hereof. The ensuing description provides embodiment(s) only and is not intended to limit the scope, applicability, or configuration of the disclosure. Rather, the ensuing description of the embodiment(s) will provide those skilled in the art with an enabling description for implementing one or more embodiments. It is understood that various changes may be made in the function and arrangement of elements without departing from the spirit and scope of this disclosure. In the following description, for the purposes of explanation, specific details are set forth in order to provide a thorough understanding of certain inventive embodiments. However, it will be apparent that various embodiments may be practiced without these specific details. The figures and description are not intended to be restrictive. The word “example” or “exemplary” is used herein to mean “serving as an example, instance, or illustration.” Any embodiment or design described herein as “exemplary” or “example” is not necessarily to be construed as preferred or advantageous over other embodiments or designs.

In current approaches, isolators can be used to safely transmit a control signal or bit-stream signal between two sections of a circuit operating with respect to different ground levels. Each channel may use two pads and two bonding wires to connect the primary die operating referenced to a first ground (low voltage ground) to the secondary die operating referenced to a second ground. When several isolated independent channels are used, a relatively large die may be utilized to fit all these differential pads. In a power switching application, various information such as many status flags, isolated temperature measurement data, isolated voltage measurement data, and/or current measurement data can be sent back. In current approaches, for such kind of data, the timing information may be lost. For example, a PWM signal may not be transmitted where the information is in the duty cycle. It also cannot transmit a sigma-delta bit-stream, as it also uses the sampling clock. Transmitting several information such as PWM and/or sigma delta bit-stream, together with various quasistatic status flags on a single digital isolator channel can be a challenge.

Embodiments of the disclosure enable transmitting a bank of bits, such as several octets coming out of various ADC converters, by merging them in a bitstream with a predefined protocol. The receiver can then receive the bitstream and can decode the bitstream to determine which octet corresponds to which data (such as isolated temperature and/or voltage). Techniques disclosed herein enable mixing two status information (such as UVLO and over-current status) and one PWM signal from a temperature sensor, along with addition of up to two bitstream, without any distortion. The PWM and bitstream frequencies may be the same. Embodiments of the disclosure enable use of a modulation technique that does not rely on a current consuming OOK approach. Embodiments of the disclosure enable direct modulation of various time sensitive signals. In some embodiments, the two status information data plus the PWM signal can be merged/encoded together to form a single digital bitstream that can be transmitted to a modulator.

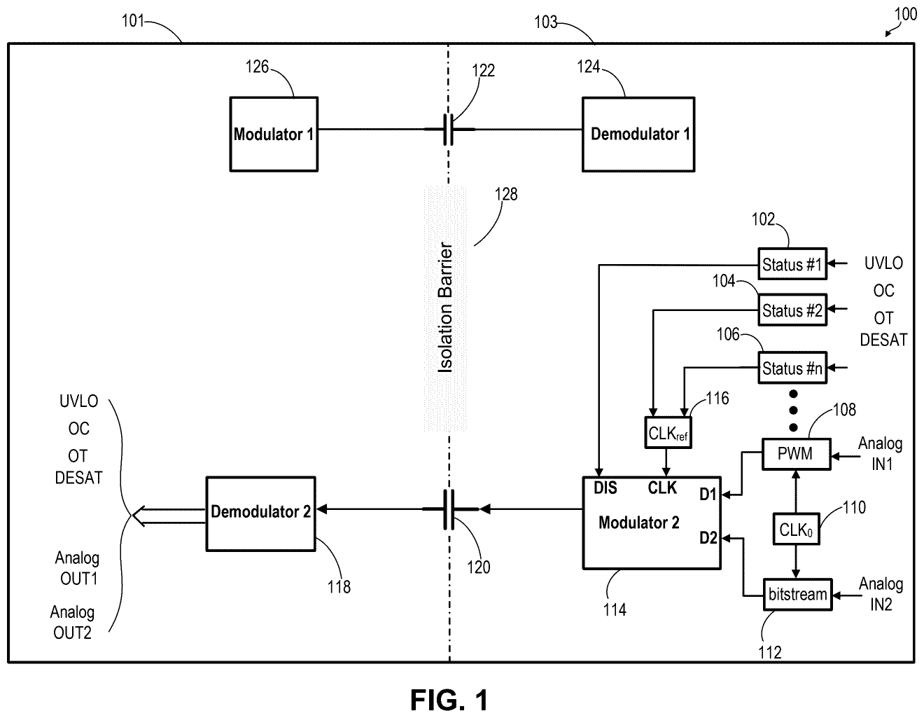

FIG. 1 illustrates an isolated gate driver circuit with a modulator, according to some embodiments. An isolated gate driver circuit 100 can include a low-voltage section 101 and a high-voltage section 103 that are isolated by an isolation barrier 128. The low-voltage section 101 can include a modulator 126 that is arranged to transmit data through the isolation capacitor 122 to a demodulator 124. The high-voltage section 103 can include a modulator 114 that is arranged to transmit data through the isolation capacitor 120 to a demodulator 118. The high-voltage section 103 can include a status indicator 102, a status indicator 104 up to status indicator 106 (status #1, #2, to #n). The status indicators can be arranged to detect and report status information such as UVLO, over-current (OC), over-temperature (OT), saturation operating condition of the power switch (DESAT) and/or other system status indicators. The outputs of the indicators 104 to 106 can be transmitted to a reference clock synchronizer circuit 116. The reference clock synchronizer circuit 116 can be arranged to synchronize the status indicator #2 to #n signals with a reference clock CLKref. The output of the indicator 102 and the reference clock synchronizer circuit 116 can be coupled to a modulator circuit 114. A PWM generator circuit 108 can be coupled to the modulator circuit 114, where the PWM circuit can be arranged to receive an analog input IN1. A clock generator circuit 110 can be coupled to the PWM circuit 108 and to a bitstream circuit 112. An output of the indicator 102 and an output of the reference clock synchronizer circuit 116 can be transmitted to the modulator circuit 114. The modulator circuit 114 can be coupled to an isolation capacitor 120, where the modulator circuit 114 can be arranged to transmit data through the isolation capacitor 120 to the demodulator 118.

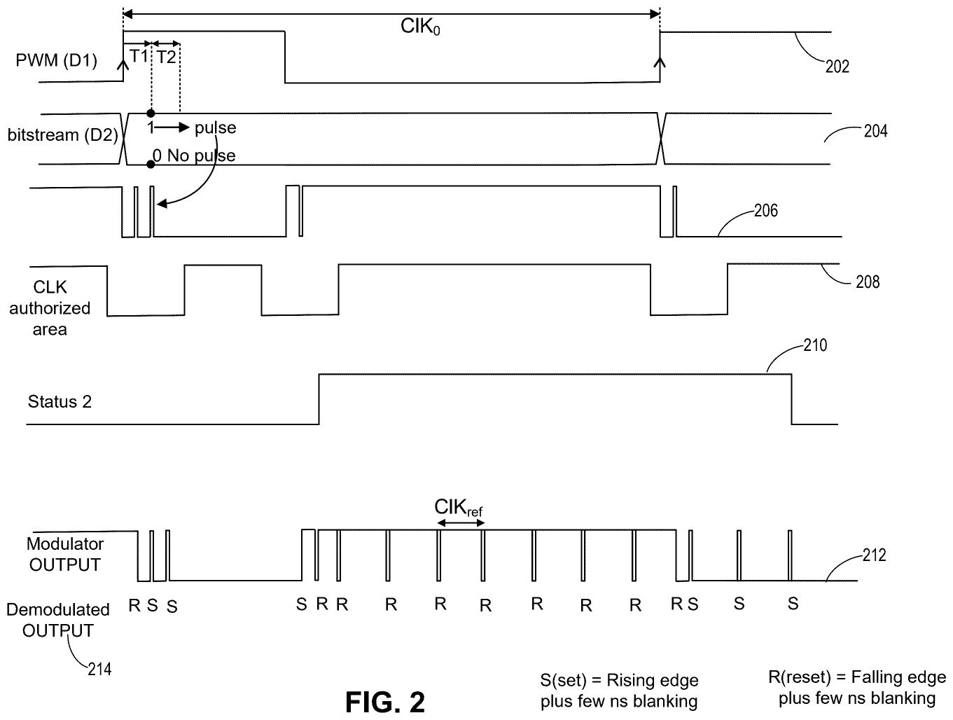

FIG. 2 illustrates a modulation scheme used by the modulator circuit 114 and the associated circuitry, according to some embodiments. FIG. 2 shows the PWM signal 202 and bitstream data 204. Graph 206 shows results of PWM signal 202 combined with bitstream data 204. FIG. 2 further shows authorized CIK area 208, status-2 indicator 210, modulator output 212 (with and without the status-2) and the demodulator output 214. In the illustrated embodiment, a reset (R) signal is a falling edge (+few ns blanking) and a set signal (S) is a rising edge (+few ns blanking). If within T1 a R-S sequence occurs, then CK0 reference can be detected. If within T2, S is detected after previous event, then bitstream is set to 1; otherwise, it is set to 0. Except during the T2 window, if more than 2 consecutive S or 2 consecutive R are detected, then CKref is active, and also Status #2 is active. If more than 2 statuses are used, CKref frequency can be adapted accordingly. Then, 2 consecutive identical pulses can be obtained within a given timeframe.

When status #1 indicator is 1, it can disable the modulator circuit 114. If the receiver receives no signals for at least CK0 period, it can detect a status #1 event (for example, this can act as a watchdog). In some embodiments, this status path may be relatively slow and can deactivate all other data bitstream. This may not be the case for status #2. #n. In some embodiments where there are more than one bitstreams, several consecutive T2 windows can be repeated. When there is no PWM signal, CK0 (50% duty cycle) can be connected to D1. Then, a second T2 window for a second bitstream can be used after the S-R sequence.

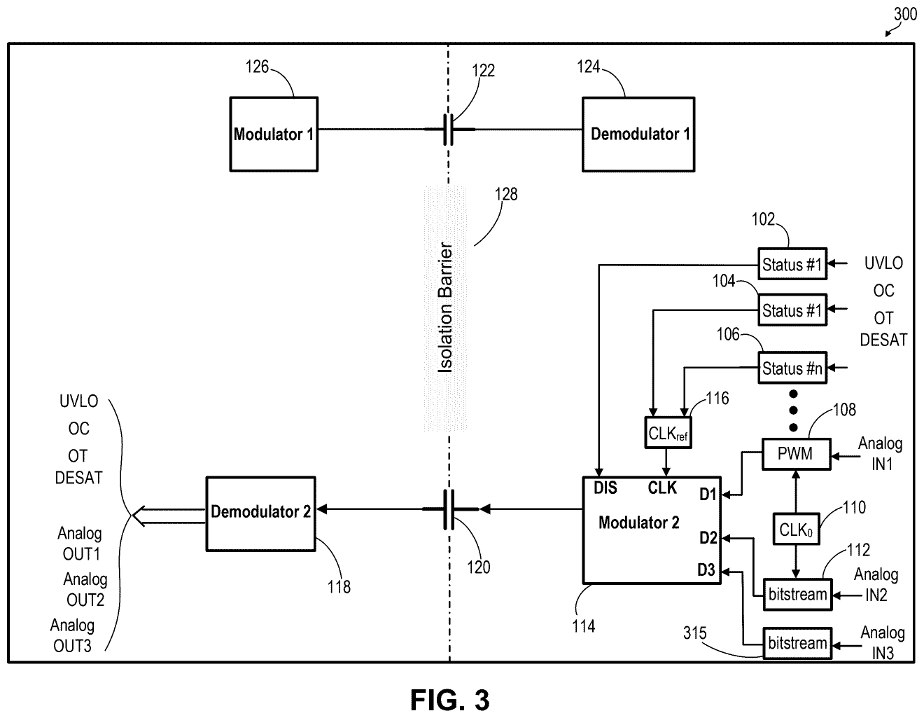

FIG. 3 illustrates an isolated gate driver circuit with a modulator having multiple bitstreams, according to some embodiments. Isolated gate driver circuit 300 is similar to the isolated gate driver circuit 100 except that it can include additional bitstreams. The isolated gate driver circuit 300 can include bitstream 315 in addition to the other circuits of isolated gate driver circuit 100.

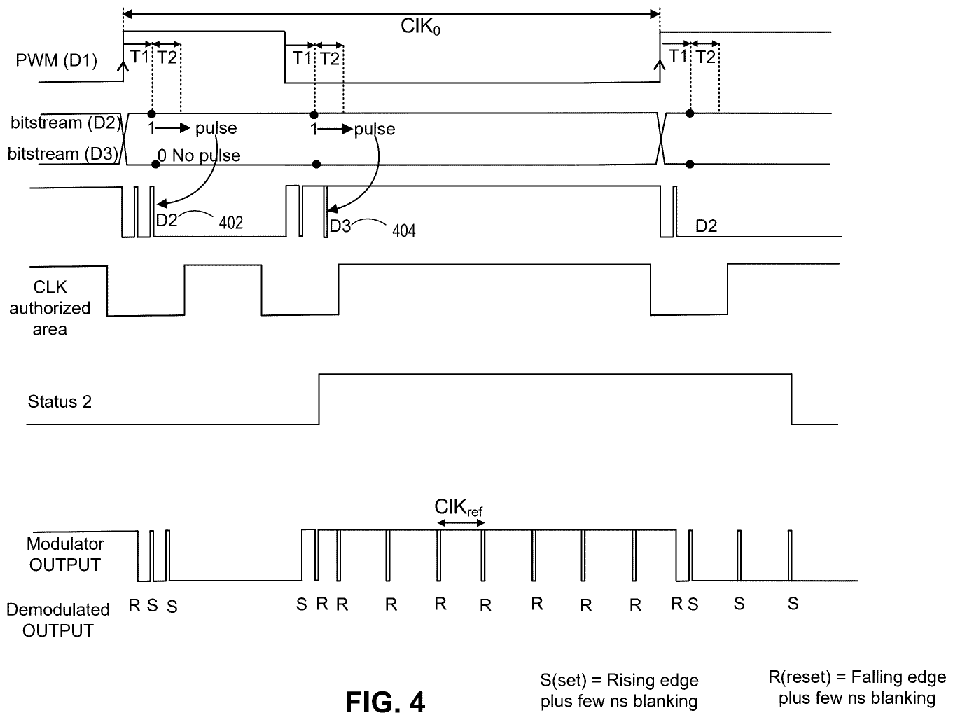

FIG. 4 illustrates modulation schemes used by the modulator circuit of FIG. 3, according to some embodiments. Referring to FIGS. 3 and 4, the second bitstream 315 can be added to the PWM by adding (or not adding) pulses 402 and 404 within T2 after a S-R sequence within T1. However, the clock reference can remain referred to the R-S sequence, as the S-R timing depends on the PWM duty-cycle.

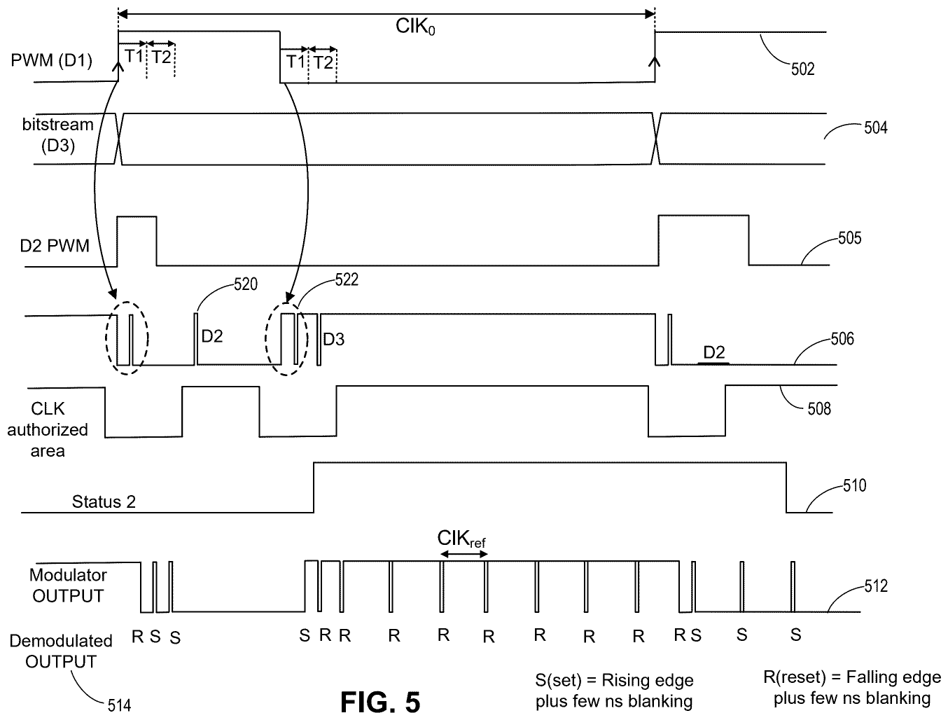

FIG. 5 illustrates a modulation scheme used by the modulator circuit 114 and the associated circuitry where modulated signals can send analog information instead of a bitstream, according to some embodiments. As illustrated in FIG. 5, graph 506 for the modulated signal may send analog information instead of a bitstream. FIG. 5 also shows graph 505 illustrating D2 PWM. FIG. 5 shows the PWM signal 502 and bitstream data 504. Graph 506 shows results of PWM signal 502 combined with bitstream data 204. FIG. 5 further shows authorized CIK area 508, status-2 indicator 510, modulator output 512 (with and without the status-2) and the demodulator output 514.

Instead of placing (or not adding) a pulse at a fixed delay from the previous pulse pattern, D2 pulse 520 may be time delayed, with the delay being proportional to the analog information that is used to be transmitted, therefore D2 can become another PWM. In some embodiments, this scheme can place a constraint on the minimum/maximum PWM (D1) duty cycle as the D2 pulse 520 appears before the next pattern 522 relative to D1. Graph 505 shows D2 PWM pattern. Its rising edge can be synchronized with the D1 PWM. Its falling edge may occur prior to the minimum D1 PWM. The falling edge of D2 can trigger a pulse over the modulated signal 505.

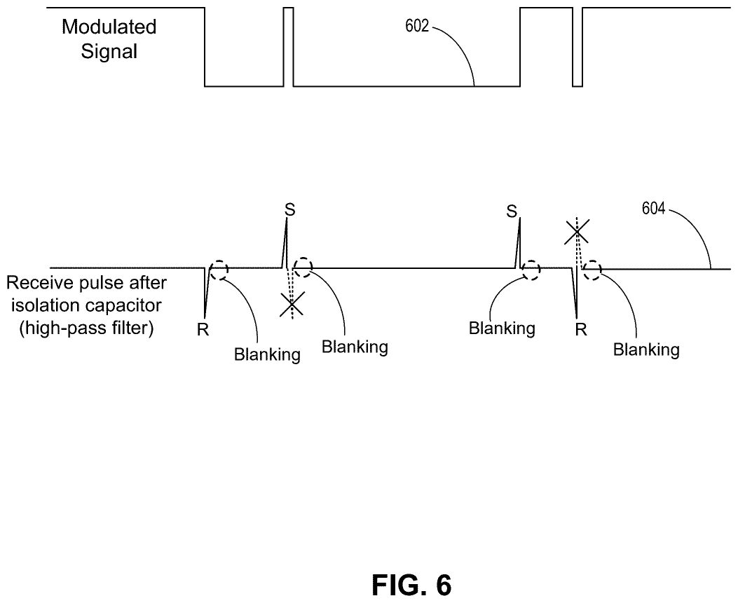

FIG. 6 illustrates a modulation and demodulation scheme used in isolated gate drivers, according to some embodiments. FIG. 6 shows a method of modulation to generate a sequence of Set and Reset signals that can be used by modulator 114. As appreciated by one of skill in the art having the benefit of this disclosure, other modulation techniques can be used to generate similar Set and Reset patterns. Graph 602 shows modulated signal and graph 604 shows received pulses after the isolation capacitor 120. In the illustrated embodiment, the Set or Reset implementation can be on the edge polarity of each transition because the second transition may be rejected when there is a short pulse. Once a S or R is detected, the receiver may be blanked for a few nano seconds (blanked portions shown on graph 604) so that for short pulses only the first edge is detected. A demodulator can detect series of non-interleaved S and R events. The demodulator may decode a sequence of S and R events. A logic and delay circuit can demodulate the modulated data without distortion of signals D1, D2 and D3 (constant delay).

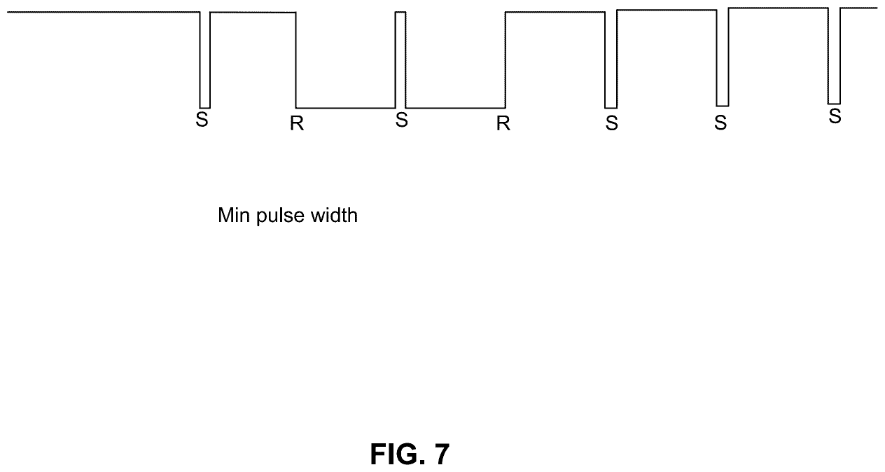

FIG. 7 illustrates a modulation scheme, according to certain embodiments. The illustrated technique in FIG. 7 can be advantageous because it can be relatively fast and can have minimum number of transitions. Embodiments of the disclosure enable generating custom set and reset patterns, that can be used by the modulator circuit 114. In some embodiments, a single edge transition can be used for a reset and a single short pulse (e.g., two consecutive fast edges) for a set. In such embodiments, the information is no longer in the edge polarity, but in the number of consecutive edges. This can double the possible bitstream of the disclosed isolator. It can also reduce the number of transitions, making it more current efficient and save power.

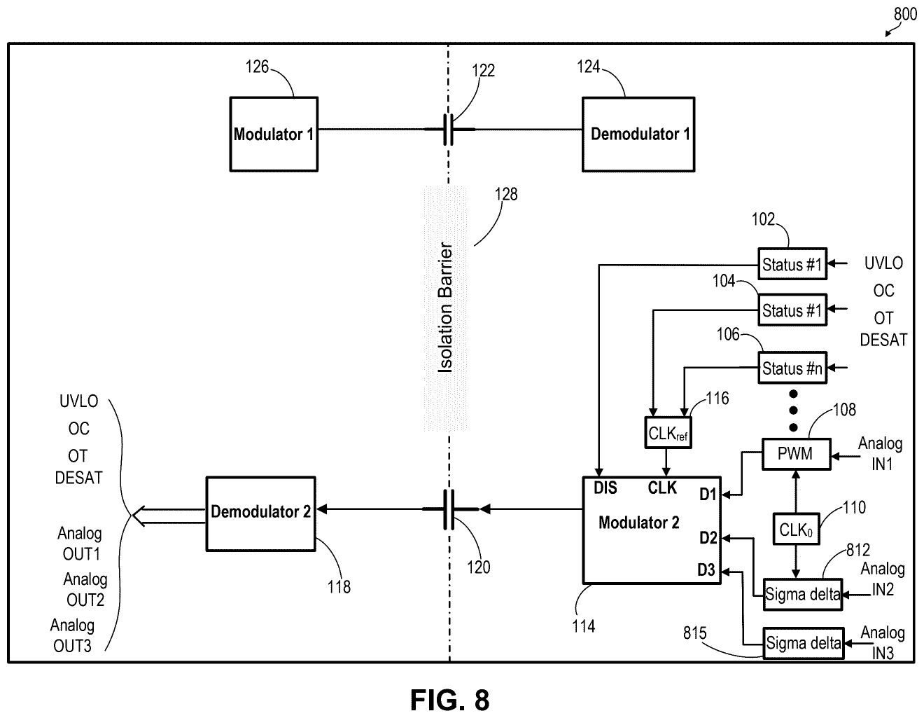

FIG. 8 illustrates an isolated gate driver circuit with a modulator having multiple sigma/delta inputs, according to some embodiments. Isolated gate driver circuit 800 is similar to the isolated gate driver circuit 300 except that it can include sigma/delta inputs 812 and 815 instead of bitstreams.

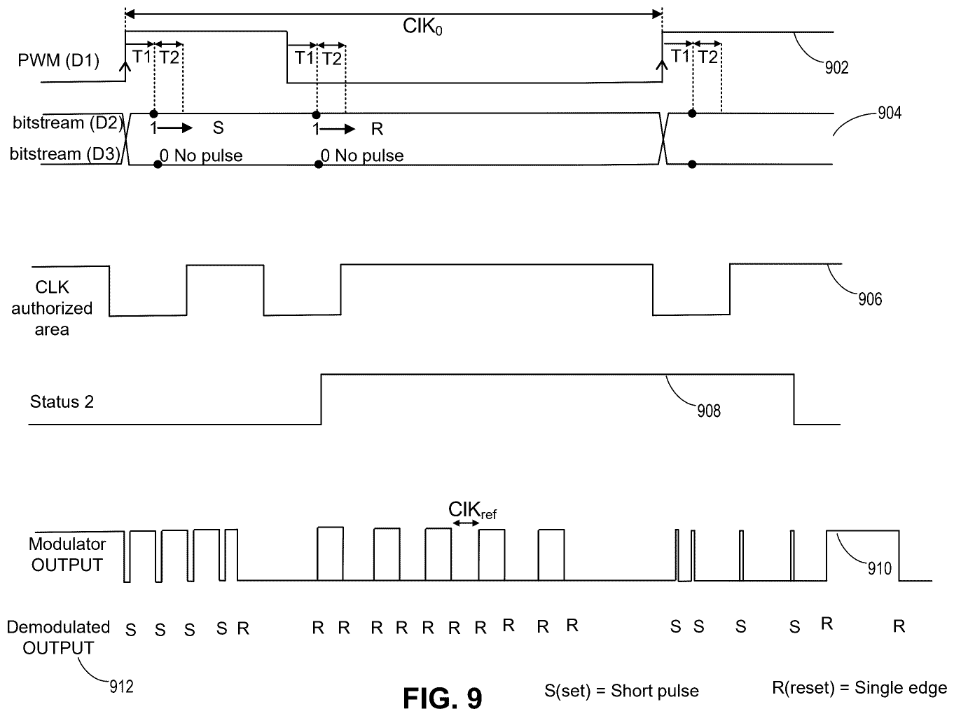

FIG. 9 illustrates a digital modulation scheme based on the scheme shown in FIG. 8, according to some embodiments. The illustrated modulation scheme is similar to the scheme in FIGS. 4-5, except that a sigma-delta input is used instead of each of the bitstreams, and the modulation technique is changed, with a different coding for set and reset events. FIG. 9 shows graphs 902, 904, 906, 908, 910 and 912. In the illustrated embodiment, at the modulator output shown in graph 910, a sequence of set and reset can be generated that can recover the three analog IN signals and the status signal. Further, the first S received may be the turn-on of the PWM D1 (and the reference clock for the two other bitstreams). After the first S (a short pulse, active low or high, it does not matter), signals are checked for presence of another S within a given narrow T2 timeframe. In this way, the state of one of the bitstream D2 can be defined. Subsequently, the presence of other consecutive S can be representative of a STATUS-2 high information. The first R (a single transition) is the turn-off of the PWM D1. If a second R is received within a fixed T2 time frame, it defines the value of the second bitstream D3. Any extra R is representative of a STATUS-2 event high. The illustrated modulation technique can be relatively faster. In the illustrated scheme, an analog receiver can distinguish a single edge vs. a short pulse.

In some embodiments, combination of the circuits and methods disclosed herein can be utilized to modulate signals on the high-voltage side of a isolator and to demodulate signals on the low-voltage side of the isolator. Although circuits and methods are described and illustrated herein with respect to several particular configuration of a gate driver modulator/demodulator and modulation/demodulation schemes, embodiments of the disclosure are suitable for use with other configurations of signal isolation modulation techniques used other power converter topologies.

In the foregoing specification, embodiments of the disclosure have been described with reference to numerous specific details that can vary from implementation to implementation. The specification and drawings are, accordingly, to be regarded in an illustrative rather than a restrictive sense. The sole and exclusive indicator of the scope of the disclosure, and what is intended by the applicants to be the scope of the disclosure, is the literal and equivalent scope of the set of claims that issue from this application, in the specific form in which such claims issue, including any subsequent correction. The specific details of particular embodiments can be combined in any suitable manner without departing from the spirit and scope of embodiments of the disclosure.

Additionally, spatially relative terms, such as “bottom or “top” and the like can be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as a “bottom” surface can then be oriented “above” other elements or features. The device can be otherwise oriented (e.g., rotated 90 degrees or at other orientations) and the spatially relative descriptors used herein interpreted accordingly.

Terms “and,” “or,” and “an/or,” as used herein, may include a variety of meanings that also is expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean any combination of A, B, and/or C, such as A, B, C, AB, AC, BC, AA, AAB, ABC, AABBCCC, etc.

Reference throughout this specification to “one example,” “an example,” “certain examples,” or “exemplary implementation” means that a particular feature, structure, or characteristic described in connection with the feature and/or example may be included in at least one feature and/or example of claimed subject matter. Thus, the appearances of the phrase “in one example,” “an example,” “in certain examples,” “in certain implementations,” or other like phrases in various places throughout this specification are not necessarily all referring to the same feature, example, and/or limitation. Furthermore, the particular features, structures, or characteristics may be combined in one or more examples and/or features.

In the preceding detailed description, numerous specific details have been set forth to provide a thorough understanding of claimed subject matter. However, it will be understood by those skilled in the art that claimed subject matter may be practiced without these specific details. In other instances, methods and apparatuses that would be known by one of ordinary skill have not been described in detail so as not to obscure claimed subject matter. Therefore, it is intended that claimed subject matter not be limited to the particular examples disclosed, but that such claimed subject matter may also include all aspects falling within the scope of appended claims, and equivalents thereof.

What is claimed is:

1. A circuit comprising:
a modulator circuit referenced to a first ground and arranged to receive at least a first status identifier signal and a second status identifier signal, a pulse width modulated (PWM) signal and a first bitstream signal, and in response generate a modulated signal;
an isolation capacitor coupled between to the modulator circuit and a demodulator circuit, wherein the modulator circuit is arranged to transmit the modulated signal through the isolation capacitor to the demodulator circuit; and
a clock generator circuit arranged to generate a clock signal (CK0), wherein the PWM signal and the first bitstream signal are synchronized with CK0; and
wherein the demodulator circuit is referenced to a second ground and is arranged to receive the modulated signal and generate output signals corresponding to the first and second status identifier signals, the PWM signal and the first bitstream signal.

2. The circuit of claim 1, wherein the demodulator circuit is arranged to detect CK0 when after a rising edge of PWM, a reset-set sequence is detected within a first time period T1.

3. The circuit of claim 2, wherein the demodulator circuit is further arranged to set the first bitstream signal to 1 when a set is detected within a second time period after CK0 is detected.

4. The circuit of claim 3, further comprising a second clock generator circuit arranged to generate a second clock signal.

5. The circuit of claim 4, wherein the demodulator circuit is further arranged to indicate that the second clock signal is active, and to indicate that the second status identifier signal is active when more than two consecutive set or two consecutive reset signals are detected.

6. The circuit of claim 5, wherein the modulator circuit is further arranged to receive a second bitstream signal.

7. The circuit of claim 6, wherein the second clock signal is mixed with the second status identifier signal and with a third status identifier signal.

8. The circuit of claim 1, wherein when the first status identifier signal is 1, the modulator circuit is disabled.

9. The circuit of claim 1, wherein the first status identifier signal corresponds to an isolated undervoltage lock-out (UVLO) signal, and the second identifier signal corresponds to an isolated overcurrent condition signal.

10. A circuit comprising:
a plurality of isolated detectors arranged to detect system operating statuses and generate a plurality of digital signals;
a pulse width generation circuit arranged to generate a pulse width modulated (PWM) signal, and at least a bitstream generator circuit arranged to generate at least a time sensitive bitstream signal; and
a modulator circuit arranged to receive the PWM signal and the time sensitive bitstream signal and in response, using sequence of set and reset commands, generate a single modulated signal, the modulator circuit further arranged to asynchronously modulate the plurality of digital signals onto the single modulated signal to generate an output modulated signal, and transmit the modulated output signal across an isolation capacitor to a demodulator circuit.

11. The circuit of claim 10, wherein the demodulator circuit is arranged to receive the modulated output signal and extract a reference clock from the modulated output signal.

12. The circuit of claim 11, wherein the demodulator circuit is arranged to regenerate the PWM signal, the time sensitive bitstream signal and the plurality of digital signals.

13. The circuit of claim 12, wherein the modulator circuit operates referenced to a first ground.

14. The circuit of claim 13, wherein the demodulator circuit operates referenced to a second ground.

15. A method of operating a circuit, the method comprising:
providing a modulator circuit referenced to a first ground;
receiving, by the modulator circuit, at least a first status identifier signal and a second status identifier signal, a pulse width modulated (PWM) signal and a first bitstream signal;
generating, by the modulator circuit, a modulated signal;
providing an isolation capacitor coupled between to the modulator circuit and a demodulator circuit; and
transmitting, by the modulator circuit, the modulated signal through the isolation capacitor to the demodulator circuit.

16. The method of claim 15, further comprising generating, by a clock generator circuit, a clock signal (CK0).

17. The method of claim 16, further comprising synchronizing the PWM signal and the first bitstream signal with CK0.

18. The method of claim 17, further comprising receiving, by the demodulator circuit, the modulated signal.

19. The method of claim 18, further comprising generating, by the demodulator circuit, output signals corresponding to the first and second status identifier signals, the PWM signal and the first bitstream signal.

20. The method of claim 19, wherein the demodulator circuit is referenced to a second ground.
